(19) United States
(12) Patent Application Publication
(10) Pub. No.: US 2008/0293192 A1
(43) Pub. Date: Nov. 27, 2008

(54) SEMICONDUCTOR DEVICE WITH STRESSORS AND METHODS THEREOF

(76) Inventors: Stefan Zollner, Hopewell Junction, NY (US); Veeraraghavan Dhandapani, Round Rock, TX (US); Paul A. Grudowski, Austin, TX (US)

Correspondence Address: ZAGORIN O'BRIEN GRAHAM LLP (115), 7600B N. CAPITAL OF TEXAS HWY., SUITE 350, AUSTIN, TX, 78731-1191, US

(21) Appl. No.: 11/751,724

(22) Filed: May 22, 2007

(51) Int. Cl. H01L 29/94; H01L 21/336

(52) U.S. Cl. 438/197; 257/288; 438/303; 257/E21.409; 257/E29.345

(57) ABSTRACT

A semiconductor device is formed in a semiconductor layer. A gate dielectric is formed over a top surface of the semiconductor layer. A gate stack is over the gate dielectric. A sidewall spacer is formed around the gate stack. Using the sidewall spacer as a mask, an implant is performed to form deep source/drain regions in the semiconductor layer. Silicon carbon regions are formed on the deep source/drain regions and a top surface of the gate stack. The silicon carbon regions are silicided with nickel.

### BACKGROUND

1. Field

This disclosure relates generally to methods of making semiconductor devices, and more specifically, to a semiconductor device with stressors and methods thereof.

2. Related Art

Stressor layers are typically used to generate stress in a channel region of a transistor to improve carrier mobility in the channel region. Stressor layers are typically deposited after silicide formation. The stress induced by the stressor layers in the channel region is a function of the temperature at which the stressor layers are formed. Because of the thermal instability of silicides at higher temperature the stressor layers cannot be formed at higher temperatures.

Accordingly, there is a need for a semiconductor device with stressors and methods thereof.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a view of a semiconductor device during a processing stage;

FIG. 2 is a view of a semiconductor device during a processing step;

FIG. 3 is a view of a semiconductor device during a processing step;

FIG. 4 is a view of a semiconductor device during a processing step;

FIG. 5 is a view of a semiconductor device during a processing step;

FIG. 6 is a view of a semiconductor device during a processing step;

FIG. 7 is a view of a semiconductor device during a processing step;

FIG. 8 is a view of a semiconductor device during a processing step; and

FIG. 9 is a view of a semiconductor device during a processing step.

### DETAILED DESCRIPTION

In one aspect, a method of forming a semiconductor device is provided. The method includes forming a gate dielectric over a top surface of a semiconductor layer. The method further includes forming a gate stack over the gate dielectric. The method further includes forming a sidewall spacer around the gate stack. The method further includes implanting, using the sidewall spacer as a mask to form deep/source drain regions in the semiconductor layer. The method further includes forming silicon carbon regions that are crystalline on the deep source/drain regions and a top surface of the gate stack. The method further includes using nickel to convert the silicon carbon regions to silicide regions.

In another aspect, a method of forming a semiconductor device is provided. The method includes forming a gate stack over a silicon layer having a polysilicon top surface. The method further includes forming deep source/drain regions in the silicon layer on opposing sides of the gate stack. The method further includes forming source/drain silicon carbon regions and a gate silicon carbon region, wherein the source/drain silicon carbon regions have an exposed top surface and are in direct contact with the deep source/drain regions and the gate silicon carbon regions have an exposed to surface and are in direct contact with the gate stack. The method further includes siliciding the source/drain and gate silicon carbon regions with nickel.

In yet another aspect, semiconductor device including a silicon layer is provided. The semiconductor device includes a gate stack over the silicon layer. The semiconductor device further includes a sidewall spacer around the gate stack. The semiconductor device further includes a deep source/drain region in the silicon layer on a side of the gate stack and substantially aligned to an edge of the sidewall spacer. The semiconductor device further includes a silicide region directly on the deep source/drain region, wherein the silicide region comprises nickel, carbon, and silicon.

FIG. 1 shows a view of a semiconductor device 10 during a processing step. Semiconductor device 10 may comprise a device formed using semiconductor material on a buried oxide layer (BOX) 14, over a substrate 12. The semiconductor material described herein can be any semiconductor material or combinations of materials, such as gallium arsenide, silicon germanium, silicon, the like, and combinations of the above. Semiconductor device 10 may further comprise a semiconductor layer 16. Semiconductor device 10 may further comprise a gate stack 18 formed over a gate dielectric layer 20. Gate dielectric layer 20 may be formed over a top surface 26 of semiconductor layer 16. A sidewall spacer 24 may be formed around gate stack 18. Prior to forming sidewall spacer 24, a liner 22 may be formed around gate stack 18. Liner 22 may extend laterally over semiconductor layer 16, as shown in FIG. 1. Using gate stack 20, as a mask source/drain extensions may be formed in semiconductor layer 16. Next, using gate stack 20, as a mask deep source/drain regions 28, 30 may be formed in semiconductor layer 16. Although FIG. 1 is explained with respect to particular steps, semiconductor device 10 may be formed using other steps, as well. Semiconductor device 10 may be a p-MOS transistor or an n-MOS transistor.

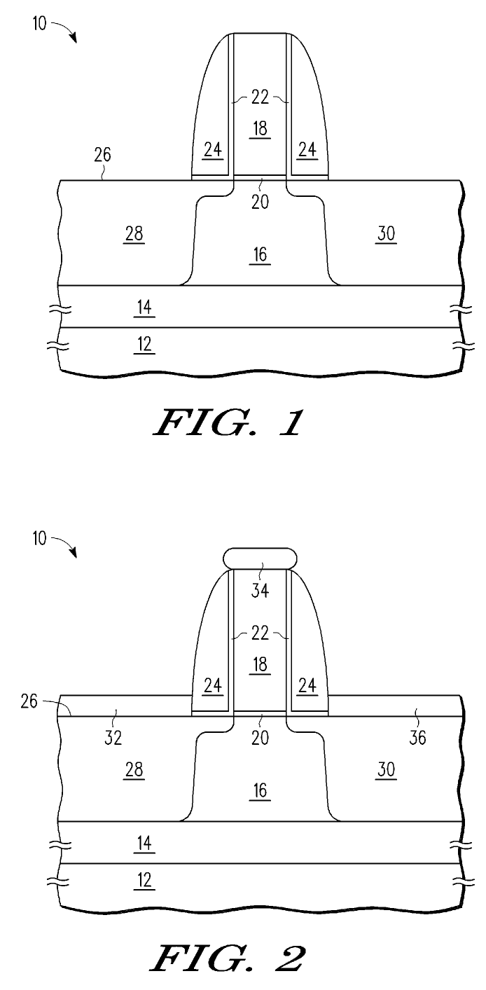

Next, as shown in FIG. 2, an epitaxial silicon carbon (Si:C) layer (carbon-doped silicon layer) may be epitaxially grown over top surface 26 of semiconductor layer 16 and a polycrystalline Si:C layer may be grown over a top surface of gate stack 18. This would result in formation of Si:C regions 32, 34, and 36, which are in direct contact with a top surface 26 of semiconductor layer 16 and the top surface of gate stack 18. In one embodiment, Si:C regions 32, 34, and 36 may have a thickness in a range from 100 to 200 Angstroms.

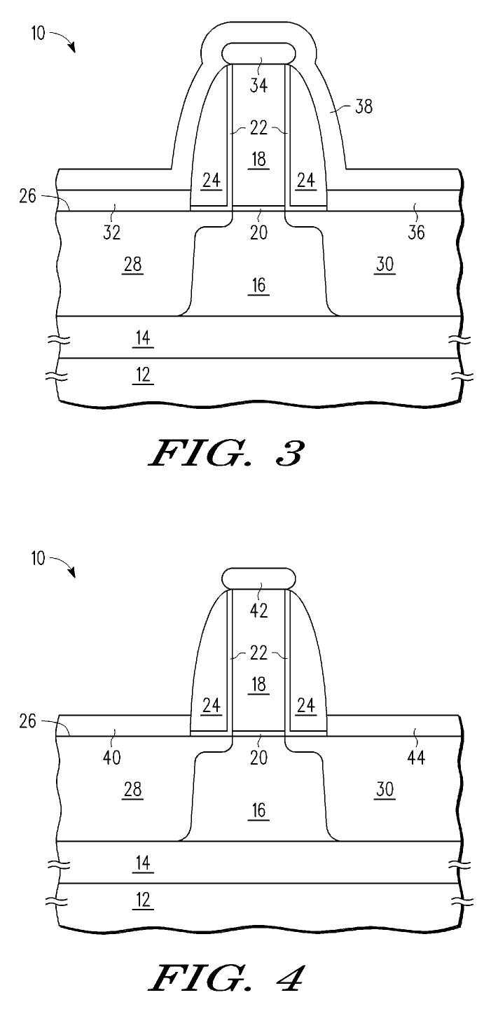

Next, as shown in FIG. 3, a metal layer 38 may be deposited over all surfaces of semiconductor device 10. Metal layer 38 may be formed by depositing nickel, nickel platinum alloy, platinum, or any other suitable metal. In one embodiment, metal layer 38 may have a thickness in a range from 50 to 150 Angstroms.

Next, as shown in FIG. 4, metal layer 38 may be subjected to an annealing step or steps (multiple anneals) and thereby forming silicide regions 40, 42, and 44. Silicide regions 40, 42, and 44 may be formed because of the reaction of the material in the metal layer 38 with underlying silicon in Si:C regions 32, 34, and 36. By way of example, the annealing step may be formed at a temperature in a range from 250 to 500 degrees Celsius. Silicide regions 40, 42, 44 may be nickel silicide carbon (NiSi:C) regions, when the deposited metal layer 38 is nickel. Alternatively, silicide regions 40, 42, and 44 may be PtSi:C regions or NiPtSi:C regions. Any remaining metal, such as Ni may be removed.

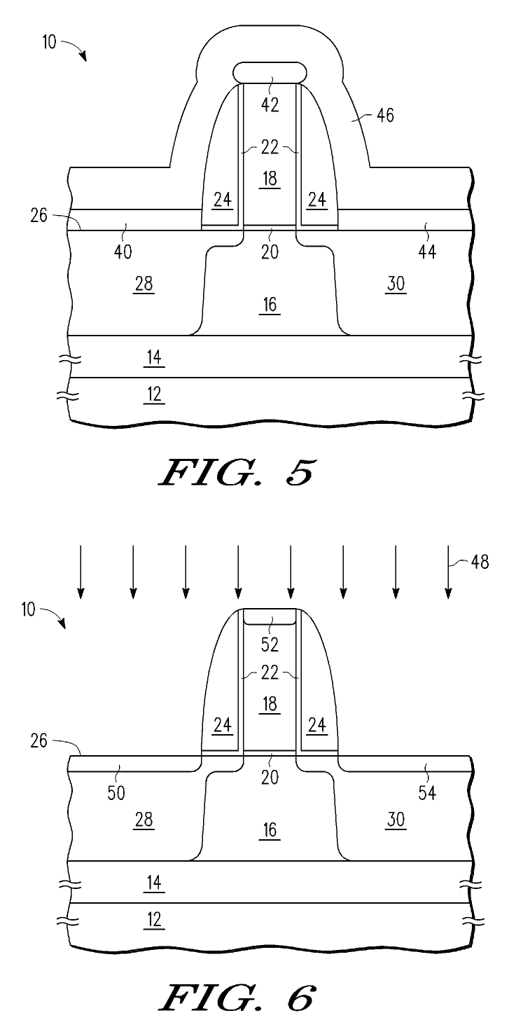

Next, as shown in FIG. 5, a stressor layer 46 may be deposited over silicide regions 40, 42, and 44. Stressor layer 46 may be deposited at a higher temperature than previously possible because of the higher stability, due to the incorporation of carbon into silicide, of silicide regions 40, 42, and 44. In one embodiment, stressor layer 46 may be deposited at a temperature of at least 550 degrees Celsius. Stressor layer 46 may be deposited using chemical vapor deposition or plasma enhanced chemical vapor deposition. Stressor layer 46 may have a thickness in a range of 300 to 800 Angstroms. Because of the higher stress created by stressor layer 46 in a channel region of semiconductor device 10 higher drive currents may be achieved. Stressor layer 46 may create a tensile stress in a channel region of semiconductor device 10 or stressor layer 46 may create a compressive stress in the channel region of semiconductor device 10. In one embodiment, stressor layer 46 may be a dual-etch stop layer, such that it may create a compressive stress in a channel region of a p-MOS transistor and it may create a tensile stress in a channel region of an n-MOS transistor. Although not described further, additional steps, such as contact formation may be performed after depositing stressor layer 46.

In an alternative embodiment, as shown in FIG. 6, amorphous Si:C regions 50, 52, and 54 may be formed by performing an amorphization implant and then performing carbon implantation 48. Carbon implantation 48 may be performed at an energy level in a range of 3 keV to 5 keV at a dosage level in a range of 5 e14 atoms/cm² to 1 e16 atoms/cm².

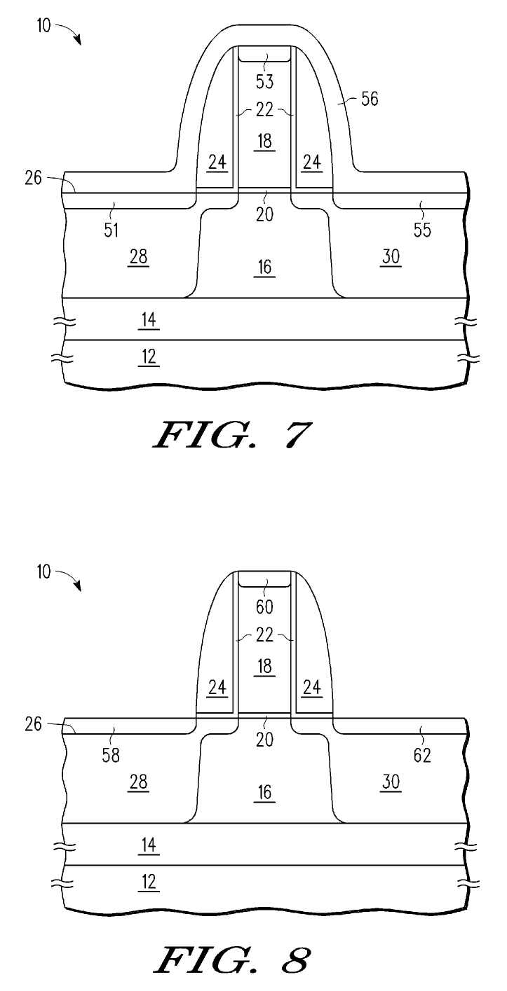

Next, as shown in FIG. 7, a metal layer 56 may be deposited over all surfaces of semiconductor device 10. Metal layer 56 may be formed by depositing nickel, nickel platinum alloy, or platinum. In one embodiment, metal layer 56 may have a thickness in a range from 50 to 150 Angstroms. Prior to the depositing of metal layer 56, amorphous Si:C regions 50, 52, and 54 may be subjected to a solid phase epitaxy (SPE) anneal resulting in the conversion of amorphous Si:C regions 50, 52, and 54 into crystalline Si:C regions 51, 53, and 55. Although FIGS. 6 and 7 illustrate a specific process for forming crystalline Si:C regions 51, 53, and 55. By way of example, crystalline Si:C regions 51, 53, and 55 may be epitaxially grown after forming recesses in semiconductor layer 16.

Next, as shown in FIG. 8, metal layer 56 may be subjected to an annealing step or steps (multiple anneals) and thereby forming silicide regions 58, 60, and 62. Silicide regions 58, 60, and 62 may be formed because of the reaction of the material in the metal layer 56 with underlying silicon in Si:C regions 51, 53, and 55. By way of example, the annealing step may be formed at a temperature in a range from 250 to 500 degrees Celsius. Silicide regions 58, 60, 62 may be nickel silicide carbon (NiSi:C) regions, when the deposited metal layer 56 is nickel. Alternatively, silicide regions 58, 60, and 62 may be PtSi:C regions or NiPtSi:C regions. Any remaining metal, such as Ni may be removed.

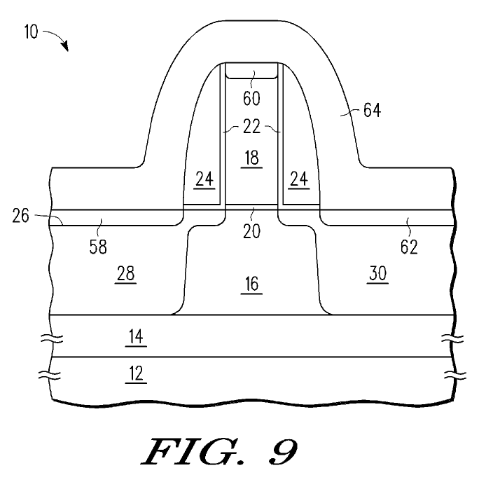

Next, as shown in FIG. 9, a stressor layer 64 may be deposited over silicide regions 58, 60, and 62. Stressor layer 64 may be deposited at a higher temperature than previously possible because of the higher stability of silicide regions 58, 60, and 62. In one embodiment, stressor layer 64 may be deposited at a temperature of at least 550 degrees Celsius. Stressor layer 64 may be deposited using chemical vapor deposition or plasma enhanced chemical vapor deposition. Stressor layer 64 may have a thickness in a range of 300 to 800 Angstroms. Because of the higher stress created by stressor layer 64 in a channel region of semiconductor device 10 higher drive currents may be achieved. Stressor layer 64 may create a tensile stress in a channel region of semiconductor device 10 or stressor layer 64 may create a compressive stress in the channel region of semiconductor device 10. In one embodiment, stressor layer 64 may be a dual-etch stop layer, such that it may create a compressive stress in a channel region of a p-MOS transistor and it may create a tensile stress in a channel region of an n-MOS transistor. Although not described further, additional steps, such as contact formation may be performed after depositing stressor layer 64.

Although the invention has been described with respect to specific conductivity types or polarity of potentials, skilled artisans appreciate that conductivity types and polarities of potentials may be reversed. In addition, although the above embodiments are discussed in terms of removal of various layers, removal does not necessarily mean a complete removal of that layer. In other words, a very small portion of the layer being removed may still be present. The presence of such small portions, however, may not affect the electrical characteristics of the semiconductor device.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of forming a semiconductor device in and over a semiconductor layer, comprising:
forming a gate dielectric over a top surface of the semiconductor layer;
forming a gate stack over the gate dielectric;
forming a sidewall spacer around the gate stack;
implanting using the sidewall spacer as a mask to form deep source/drain regions in the semiconductor layer;
forming silicon carbon regions that are crystalline on the deep source/drain regions and a top surface of the gate stack; and
using nickel to convert the silicon carbon regions to silicide regions.

2. The method of claim 1 further comprising depositing a stressor layer, after the step of siliciding, over the deep source/drain regions and the gate stack.

3. The method of claim 2, wherein the step of depositing the stressor layer is further characterized as performing a chemical vapor deposition at a temperature of at least 550 degrees Celsius.

4. The method of claim 3, wherein the step of depositing the stressor layer is further characterized by the stressor layer comprising nitride.

5. The method of claim 1, wherein the step of forming the silicon carbon regions is further characterized by removing portions of the deep source/drain regions at the surface of the semiconductor layer and a portion from the gate stack at a top surface of the gate stack and then epitaxially growing the silicon carbon regions.

6. The method of claim 1, wherein the step of forming the silicon carbon regions is further characterized by:
performing an implant into the deep source/drain regions and a top surface of the gate stack to form amorphous regions;
implanting carbon into the amorphous regions to form carbon-doped amorphous regions; and
annealing to convert the carbon-doped amorphous regions to the silicon carbon regions that are crystalline.

7. The method of claim 1, wherein the step of forming the silicon carbon regions is further characterized by epitaxially growing the silicon carbon regions on the deep source/drain regions and a top surface of the gate stack.

8. The method of claim 7, wherein the step of using nickel is further characterized as using an alloy of platinum and nickel.

9. The method of claim 7 wherein the step of siliciding is further characterized by:
depositing a layer comprising nickel;
heating to cause silicidation of the silicon carbon regions; and
removing remaining portions of the layer comprising nickel.

10. The method of claim 9, wherein the step of depositing the layer is further characterized by the layer comprising platinum.

11. The method of claim 1 further comprising performing an implant to form source/drain extensions in the substrate adjacent to the gate stack.

12. A method of forming a semiconductor device in and over a silicon layer, comprising:
forming a gate stack over the silicon layer having a polysilicon top surface;
forming deep source/drains in the silicon layer on opposing sides of the gate stack;
forming source/drain silicon carbon regions and a gate silicon carbon region, wherein the source/drain silicon carbon regions have an exposed top surface and are in direct contact with the deep source/drain regions and the gate silicon carbon regions have an exposed to surface and are in direct contact with the gate stack; and
siliciding the source/drain and gate silicon carbon regions with nickel.

13. The method of claim 12, wherein the step of forming the gate and source/drain silicon carbon regions is further characterized by removing portions of the deep source/drain regions at the surface of the silicon layer and a portion from the gate stack at a top surface of the gate stack and then epitaxially growing the source/drain and gate silicon carbon regions.

14. The method of claim 12, wherein the step of forming gate and source/drain the silicon carbon regions is further characterized by:
performing an implant into the deep source/drain regions and a top surface of the gate stack to form amorphous regions;
implanting carbon into the amorphous regions to form carbon-doped amorphous regions; and
annealing to convert the carbon-doped amorphous regions to the source/drain and gate silicon carbon regions.

15. The method of claim 12, wherein the step of forming the source/drain and gate silicon carbon regions is further characterized by epitaxially growing the silicon carbon regions on the deep source/drain regions and a top surface of the gate stack.

16. The method of claim 12, wherein the step of forming deep source/drain regions comprises forming a sidewall spacer around the gate stack and implanting into the semiconductor layer using the sidewall spacer as a mask, the method further comprising performing an implant to form source/drain extensions in the substrate adjacent to the gate stack.

17. The semiconductor device of claim 12, wherein the step of siliciding is performed using an alloy of platinum and nickel.

18. A semiconductor device, comprising:
a silicon layer;
a gate stack over the silicon layer;
a sidewall spacer around the gate stack;
a deep source/drain region in the silicon layer on a side of the gate stack and substantially aligned to an edge of the sidewall spacer;
a silicide region directly on the deep source/drain region, wherein the silicide region comprises nickel, carbon and silicon.

19. The semiconductor device of claim 18, wherein the silicide region further comprises platinum.

20. The semiconductor device of claim 18 further comprising a stressor layer over the gate stack and the deep source/drain region.
